(19) United States
(12) Patent Application Publication
(10) Pub. No.: US 2021/0222626 A1
(43) Pub. Date: Jul. 22, 2021

(54) FUNCTIONALLY GRADED SANDPHOBIC BLENDED COMPOSITE COATINGS

(71) Applicant: U.S. Army Combat Capabilities Development Command Army Research Laboratory, Adelphi, MD (US)

(72) Inventors: Andy Nieto, Marina, CA (US); Michael J. Walock, Bel Air, MD (US); Anindya Ghoshal, Phoenix, MD (US); Blake D. Barnett, Colombus, OH (US); Clara M. Mock, Belcamp, MD (US); Mark L. Graybeal, Conowingo, MD (US); Marc S. Pepi, Oxford, PA (US); Muthuvel Murugan, Abingdon, MD (US)

(21) Appl. No.: 16/748,971

(22) Filed: Jan. 22, 2020

(51) Int. Cl. F02C 7/24; C23C 14/28; C23C 14/08; C23C 16/40

(52) U.S. Cl. CPC F02C 7/24; C23C 14/28; C23C 14/081; F05D 2300/603; F05D 2230/90; F05D 2220/32; F05D 2230/31; C23C 16/403

(57) ABSTRACT

A thermal barrier coating (TBC) material includes calcic-magnesia-alumina-silicates-resistant rare-earth (RE) oxide powder blended with yttria-stabilized zirconia (YSZ). The RE oxide powder may include any of gadolinium oxide, samarium oxide, ytterbium oxide and cerium oxide. The RE oxide powder may include gadolinium zirconate (GZO).

### CROSS-REFERENCE TO RELATED APPLICATION(S)

This application claims the benefit of U.S. Provisional Patent Application No. 62/847,980 filed on May 15, 2019, which is incorporated herein by reference in its entirety.

### GOVERNMENT INTEREST

The embodiments herein may be manufactured, used, and/or licensed by or for the United States Government without the payment of royalties thereon.

### BACKGROUND

### Technical Field

The embodiments herein generally relate to thermal barrier coatings (TBCs), and more particularly to thermal barrier coatings that are resistant to environmental particulate (e.g., calcia-magnesia-alumina-silicates (CMAS)) attack.

### Description of the Related Art

Next generation gas turbine engines used in various types of applications require increasing operating temperatures in order to reap improvements in thermodynamic efficiency and engine performance. The technological demand for increased operating temperatures has largely been met through the use of TBCs that protect the nickel superalloy components, such as turbine nozzle blades and vanes. However, increasing operating temperatures, which are currently in excess of 1240° C., are now inducing environmental particulate attack on TBCs. Environmental particulates, including volcanic ash, sand, salt, and fly ash, are found in environments that affect aircraft, as well as industrial gas turbine engines for power generation. These particles have a complex composition that exhibit variable properties and a range of melting temperatures. However, these particles in the molten state form CMAS which causes degradation of TBCs on turbine blades and vanes. This CMAS-induced TBC degradation, which is collectively referred to as CMAS attack, can involve molten infiltration into open pores, chemical reactions with TBC constituents, and adhesion resulting in deposit build up on gas turbine engine components. Conventional protective coatings generally do not successfully resist CMAS attack while maintaining the low thermal conductivity and high thermomechanical stability necessary to survive harsh engine operating conditions. Therefore, there is a need to develop a new generation of TBCs that exhibit enhanced resistance to CMAS attack, while maintaining excellent erosion resistance, strain tolerance, oxidation resistance and durability under environmental particulate laden high temperature combustion flows.

### SUMMARY

In view of the foregoing, an embodiment herein provides a thermal barrier coating (TBC) material comprising calcia-magnesia-alumina-silicates-resistant rare-earth (RE) oxide powder blended with yttria-stabilized zirconia (YSZ). The RE oxide powder may comprise any of gadolinium oxide, samarium oxide, ytterbium oxide, cerium oxide, or a combination thereof. The RE oxide powder may comprise gadolinium zirconate (GZO).

Another embodiment provides a composite structure comprising a substrate; a bond coat; and a TBC over the bond coat, wherein the TBC comprises CMAS-resistant RE oxide powder blended with YSZ. The substrate may comprise a metallic substrate. The substrate may comprise a ceramic substrate. The RE oxide powder may be approximately 10 to 90 weight % of the thermal barrier coating. The TBC may be approximately 100 to 1000 μm in thickness. The RE oxide powder may comprise any of gadolinium oxide, samarium oxide, ytterbium oxide, cerium oxide, or combination thereof. The RE oxide powder may comprise GZO.

Another embodiment provides a method of forming a layered or gradient composite structure, the method comprising providing a substrate; depositing a bond coat layer over the substrate; and depositing a TBC layer over the substrate, wherein the TBC layer comprises CMAS-resistant RE oxide powder blended with YSZ. The TBC layer may be deposited using an air plasma spray. The TBC layer may be deposited using a solution precursor plasma spray. The TBC layer may be deposited using a suspension plasma spray. The TBC layer may be deposited using electron beam-physical vapor deposition. The TBC layer may be deposited using sol-gel deposition. The TBC layer may be deposited using aerosol deposition. The TBC layer may be deposited using chemical vapor deposition. The method may further comprise depositing the bond coat layer on the substrate prior to depositing the TBC layer. The TBC layer may be deposited at a thickness of approximately 100 to 1000 μm.

The embodiments herein provide, for the first time, a blended, composite TBC that is resistant to CMAS attack. The embodiments herein also include a graded coating as a way to optimize the CMAS resistance and mechanical properties as a function of top-coat thickness. The conventional technology uses a single constituent top coat comprising of YSZ, which is susceptible to CMAS attack.

These and other aspects of the embodiments herein will be better appreciated and understood when considered in conjunction with the following description and the accompanying drawings. It should be understood, however, that the following descriptions, while indicating exemplary embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1a is a scanning electron micrograph (SEM) image illustrating a thermal barrier coating (TBC) material, according to an embodiment herein;

FIG. 1b is a SEM image illustrating a uniform distribution of Gd₂O₃ splats throughout the YSZ matrix, according to an embodiment herein;

FIG. 1c is a SEM image illustrating TBC material that is sealed to a substrate to inhibit CMAS attack, according to an embodiment herein;

FIG. 2a is a SEM image illustrating a TBC coating showing CMAS accumulation on a surface with the remainder of the coating exhibiting minimal microstructural changes, according to an embodiment herein;

FIG. 2b is a SEM image illustrating a bond coat (BC) exhibiting signs of increased oxidation with the inset illustrating the formation of oxides leading to cracking at the BC/TBC interface, according to an embodiment herein;

FIG. 2c is a SEM image illustrating Gd₂O₃ coating surviving with localized erosion, according to an embodiment herein;

FIG. 2d is a SEM image illustrating a Gd₂O₃ phase in a YSZ/Gd₂O₃ composite exhibiting localized cracking, according to an embodiment herein;

FIG. 3a is an energy dispersive spectroscopy (EDS) map secondary electron image of engine tested TBC material at an interface between CMAS and a Gd₂O₃ top coat, with circled regions denoting the interaction product between CMAS and the Gd₂O₃ top coat, according to an embodiment herein;

FIG. 3b is an O map of the EDS of FIG. 3a, according to an embodiment herein;

FIG. 3c is an Al map of the EDS of FIG. 3a, according to an embodiment herein;

FIG. 3d is a Ca map of the EDS of FIG. 3a, according to an embodiment herein;

FIG. 3e is a Si map of the EDS of FIG. 3a, according to an embodiment herein;

FIG. 3f is a Gd map of the EDS of FIG. 3a, according to an embodiment herein;

FIG. 3g is a Y map of the EDS of FIG. 3a, according to an embodiment herein;

FIG. 3h is a Zr map of the EDS of FIG. 3a, according to an embodiment herein;

FIG. 4a is a SEM image illustrating CMAS deposit cross-sections on engine test TBCs with the CMAS deposit shown with significant porosity distributed throughout the structure, according to an embodiment herein;

FIG. 4b is a focused ion beam (FIB) polished and 52° tilted ion induced SEM image illustrating CMAS with large interconnected pore structures, according to an embodiment herein;

FIG. 4c is a SEM image illustrating a CMAS deposit showing crystalline phases embedded in a brittle glassy binder, according to an embodiment herein;

FIG. 4d is a FIB polished and 53° tilted ion induced SEM image of glassy binders with ‘swirl’ features, according to an embodiment herein;

FIG. 4e is a SEM image illustrating CMAS deposits with several distinct crystalline phases, according to an embodiment herein;

FIG. 4f is a FIB polished and 53° tilted ion induced SEM image of crystalline phases with CMAS deposits, according to an embodiment herein;

FIG. 5 is a flow diagram illustrating a method of forming a layered or gradient composite structure, according to an embodiment herein; and

FIG. 6 is a SEM image of a microstructure of YSZ-17 vol. % Gd₂O₃, according to an embodiment herein.

### DETAILED DESCRIPTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

The embodiments herein provide a multi-layer composite thermal barrier coating (TBC) that is resistant to environmental particulate (i.e., CMAS) attack. The new TBC uses a composite approach to incorporate the favorable mechanical properties of yttria-stabilized zirconia (YSZ), with the CMAS-resistance of rare earth (RE) based oxides. YSZ has excellent damage tolerance and toughness, and is a superb thermal barrier. However, it has been shown to be prone to deterioration by CMAS attack. RE-based oxides have superior tolerance against CMAS attack as well as oxidation resistance; however, RE oxides have lower toughness and higher thermal conductivity than YSZ.

A composite coating enables favorable attributes of each system to be incorporated into one coating, thereby mitigating the disadvantages of each individual constituent. In addition to the composite blends, the new TBC may be graded such that the one constituent could be more concentrated towards the outer surface of the coating and the other constituent towards the bond coat such that the favorable properties represented by each constituent can be used at the most advantage. For example, the RE oxides may be concentrated towards the outer surface to provide the most CMAS-resistance whereas the YSZ may be more concentrated towards the bond coat to provide strength, toughness and compatibility with the bond coat. A concentration gradient of each constituent between the two extremes can ensure maximum durability of the overall coating. The embodiments herein may provide a new class of TBCs that are tough, durable, thermally insulating, and resistant to attack from environmental particulates such as sand, salt, fly ash, volcanic ash, runway debris, etc. These coatings may extend the life of gas turbine engine components in aviation and energy applications, where the presence of environmental particulates creates an austere environment that degrades components and performance.

An experimental study investigating several TBCs for maintaining damage tolerance and attaining improved resistance to molten environmental particulate (i.e., CMAS) deposition is described below. TBC approaches include an air plasma sprayed composite and layered coating, an electron beam-physical vapor deposition (EB-PVD) doped coating, and an EB-PVD bilayer doped coating. The TBCs are evaluated under sand laden combustion flows within a gas turbine engine. Scanning electron microscopy (SEM) and nanoindentation are used to characterize the microstructural and mechanical property evolution to understand the effects of the engine conditions on the various microstructural architectures and compositions investigated. The CMAS accumulation on each TBC is characterized and the nature of interaction at the TBC/CMAS interface is characterized by SEM, focused ion beam milling/imaging, and energy dispersive spectroscopy. An air plasma sprayed composite YSZ/Gd₂O₃ coating with a thin ˜10 μm Gd₂O₃ top coat experimentally performs the best, as it exhibits the lowest CMAS deposition and the least amount of structural damage.

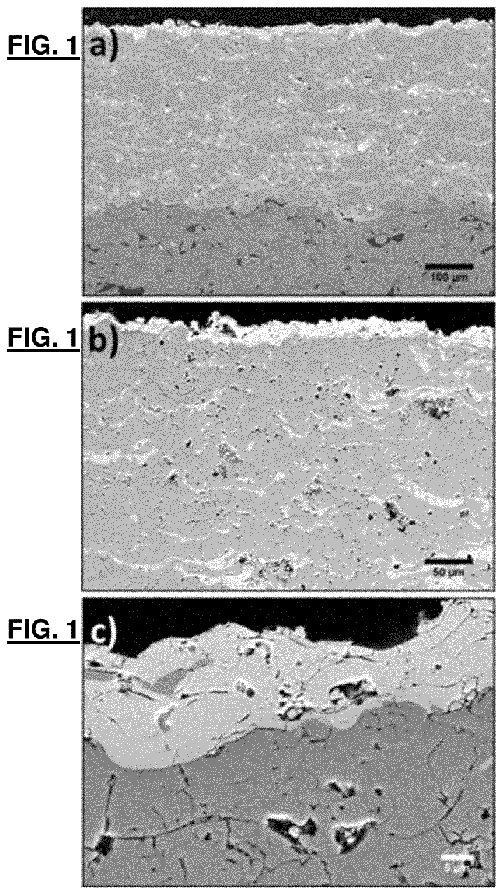

Referring now to the drawings, and more particularly to FIGS. 1a through 6, where similar reference characters denote corresponding features consistently throughout the figures, there are shown preferred embodiments. In the drawings, the size and relative sizes of components, layers, and regions, etc. may be exaggerated for clarity.

YSZ is the current state-of-the-art technology and has been widely used in the industry because of its unique combination of thermal and mechanical properties making it an ideal TBC for the current generation of gas turbine engines. A good thermal barrier coating should have the following characteristics: low thermal conductivity, similar coefficient of thermal expansion as the substrate material, strain tolerance (to compensate for thermal expansion during heating and cooling cycles), phase stability, high resistance to fracture and deformation (i.e., hardness and fracture toughness), the ability to survive in an oxidizing atmosphere, low density and to be thermodynamically compatible with the bond coat oxide.

However, more recently, aircraft and rotorcraft have reported significant power loss and premature failure of the engine after operating in austere environments such as deserts, near volcanos or in heavily polluted air such as in metropolitan cities. In all cases, premature failure occurred because of engine ingestion of airborne particulates largely comprising of CMAS. CMAS-related damage of the gas turbine engine occurs by two major pathways: (1) CMAS accumulates on the turbine blade resulting in clogged air pathways resulting in significant power losses (short term failure), and (2) CMAS infiltration of the thermal barrier coating on hot section components resulting in severe reduction of the engine lifetime and possible TBC spallation (longer term failure). Rare earth oxides have generated significant interest as potential CMAS resistant thermal barrier coatings. Of those oxides, gadolinium zirconate (GZO) is one of the more popular potential TBCs for CMAS-resistant thermal barrier coatings in gas turbine environments. GZO reacts with the CMAS to form apatite and fluorite phases sealing the remaining TBC from further CMAS infiltration. However, the relatively low fracture toughness and poor erosion resistance of GZO has prevented its widespread application.

This is the first time a blended, composite TBC has been presented that is resistant to CMAS attack. The embodiments herein also provide for a graded coating as a way to optimize the CMAS resistance and mechanical properties as a function of top-coat thickness. The conventional solutions use a single constituent top coat comprising of YSZ, which is susceptible to CMAS attack. Accordingly, the embodiments herein tackle the problem of CMAS adherence and hot corrosion attack on blades in the hot section of gas turbine engines.

One approach for mitigating CMAS attack has been to incorporate RE elements, particularly gadolinium, typically in the form of gadolinia within a yttria stabilized-zirconia (YSZ) based TBC. The incorporation of Gd₂O₃ into ZrO₂, to form Gd₂O₃+2ZrO₂ (Gd2Zr₂O₇), has shown success in hindering the infiltration of molten CMAS by inducing melting point depression that then crystallizes the molten flow via precipitation of Zr(Gd,Ca)Oₓ based fluorite and Ca₂Gd₈(SiO₄)₆O₂ based apatite phases.

An experimental study is described below, which is conducted on several composite, layered, and doped TBCs that incorporate the TBC design strategies discussed above. The parameters described below such as the materials, ranges, configurations, amounts, equipment, etc. described below are examples only and the embodiments herein are not restricted to these particular parameters. An air plasma sprayed (APS) composite coating comprising of YSZ and Gd₂O₃ is developed in order to incorporate the CMAS resistance of Gd₂O₃ into the tough and low thermal conductivity YSZ coating. In addition, a thin top layer of Gd₂O₃ is deposited in order to prevent the initial adhesion and infiltration of the CMAS.

This experimental study evaluates TBCs designed for CMAS resistance under a full-scale sand laden engine test. Full-scale engine tests are experimentally used to evaluate prospective TBC systems. The experimental study focuses on the microstructural evolution of the TBCs that performed best during the full engine tests, based on their survivability and resistance to CMAS accumulation. Characterization of microstructural evolution and mechanical properties is conducted to evaluate the effectiveness and response of each TBC design in order to guide future TBC development.

Materials

Thermal barrier coatings are sprayed onto gas turbine engine nozzle doublets, for full-scale engine tests, as well as on steel coupons that serve as witness specimens for pre-engine test coating characterization. A composite and layered coating is deposited using a PG-140 (available from Baystate Surface Technology, Auburn, Mass.) plasma spray torch, operating at 40 V, 950 A, and 47.5 kW. Argon and helium are used as the primary and secondary gases, respectively, and the powder is fed externally into the plasma plume. The bond coat is deposited using gas atomized Ni-23Co-17Cr-12Al-0.5Y powder (available from Amdry 365-2, Oerlikon Metco, Westbury, N.Y.). The feedstock powder for the ceramic TBC layer comprises of blended YSZ/Gd₂O₃ powders (70 wt % YSZ). The YSZ powder has a composition of 8 wt % Y₂O₃—ZrO₂ (Metco 204NS). The Gd₂O₃ powder is 99.99% Gd₂O₃ with a particle size of <10 μm (#11290, Alfa Aesar). An additional thin layer of Gd₂O₃ is deposited on top of the YSZ/Gd₂O₃ composite coating. This sample is referred to as AN2.

Full-Scale Engine Test with Sand Ingestion

The coating is assembled (i.e., applied) into a full nozzle ring assembly. The nozzle ring is then inserted into a turboshaft gas turbine engine rig with integrated sand ingestion capability. The sand used is AFRL-03 (available from Powder Technology Inc., Schofield, Wis.), which is a known CMAS-forming synthetic sand that comprises of a blend of several mineral compounds. The compositions of AFRL-03 sand is approximately: 34 wt % quartz (SiO₂), 30 wt % gypsum (CaSO₄.2H₂O), 17 wt % aplite (NaAlSi₃O₈), 14 wt % dolomite (CaMg(CO₃)₂), and 5 wt % salt (NaCl). The engine cycle comprises of two 25 min cycles, where the maximum temperature is approximately 1200° C., with periodic peaks of up to 1300° C. Each cycle has two periods of sand ingestion, each lasting approximately 30 s, in which the temperature is held at approximately 1240° C. The first ingestion occurs after the cycle has run for 662 s and the second occurs after 870 s. The sand loading during the first engine cycle is 129 mg/m³ to the turbine, where the units signify the amount of sand per volume of air. During the second engine cycle, the sand loading to the turbine is increased to 516 mg/m³.

Materials Characterization

Post-engine test, the full nozzle ring is disassembled, and the nozzle doublets with coatings to be characterized are mounted in resin. Mounting of the nozzle doublets is conducted prior to sectioning, in order to preserve the CMAS deposits. Sectioned nozzle doublets are then polished using alumina-based slurries down to 1 μm, followed by a 0.5 μm silica-based slurry polish. The polished cross-sections are observed under a ZEISS LSM700 confocal microscope in order to assess the thickness of CMAS deposits throughout the turbine vane airfoil perimeter. A Hitachi 4700 SEM, operating at 20 kV and equipped with an Oxford Octane EDS detector, is utilized to characterize the microstructure and elemental composition of the as-deposited coatings. A FEI NanoSEM 600, operating at 15 kV and equipped with an EDAX EDS detector, is utilized to characterize the microstructure and elemental composition of the engine tested coatings. A dual beam FEI Nanolab FIB-SEM is used to further characterize coatings and CMAS deposits. A Hysitron Triboindenter 950 nanoindenter is utilized to measure the hardness and elastic modulus of the coatings prior to and after the engine test. A Berkovich tip with a 150 μm tip radius is used, with a load cycle comprising of a 10 s ramp to a maximum load of 2000 μN, a 3 s hold at max load, and a 10 s unloading to zero load. At least 15 indentation tests are conducted on each specimen. Indentations are performed randomly on all specimens, that is, no specific phases or regions are targeted within a given coating or layer. The elastic modulus is calculated from the load-displacement unloading curve using the well-known Oliver-Pharr method.

Microstructural Design of TBCs

The microstructures of the as-deposited coatings are shown in FIGS. 1a, 1b, 1c. The plasma sprayed AN2 TBC utilizes a layered and composite approach. The AN2 coating comprises of a ˜200 μm NiCoCrAlY bond on the substrate, followed by a composite ˜350 μm YSZ/Gd₂O₃ layer, which is then topped off with a thin ˜10 μm Gd₂O₃ coating. The coating thickness varies (as expected due to the nature of thermal spray processing) from 5 to 25 μm. The composite YSZ/Gd₂O₃ layer (FIG. 1b) is designed to incorporate sufficient amount of Gd₂O₃ that can serve as a CMAS inhibitor, should the top Gd₂O₃ coating fail or become infiltrated by excessive CMAS. The thin Gd₂O₃ layer (FIG. 1c) is designed to act as a CMAS inhibiter, to effectively seal the underlying composite ceramic from CMAS attack, by reacting with and crystallizing any molten CMAS deposits that form on the surface. A blended composite approach is utilized in order to preserve the individual YSZ and Gd₂O₃ phases, thereby enabling the retention of the favorable properties of each to be utilized without forming the solid solution product, Gd₂Zr₂O₇. The solubility between the phases does however make it likely that a strong interface between Gd₂O₃ and YSZ is formed. However, it can be seen from FIG. 1b that blending is sufficient to create a uniform distribution of Gd₂O₃ splats throughout the YSZ matrix.

Mechanical Properties of TBCs

The elastic modulus and nanohardness of the AN2 coating are presented in Table 1.

TABLE 1
Elastic modulus and nanohardness of as-deposited
and engine tested AN2 coating (2000 μN)

| As-deposited | | Engine tested coatings | |
|---|---|---|---|
| Elastic modulus | Nonohardness | Elastic modulus | Nonohardness |
| (GPa) | (GPa) | (GPa) | (GPa) |
| 149.0 ± 19.0 | 14.8 ± 1.6 | 140.1 + 10.9 | 11.9 + 1.5 |

The elastic modulus values of the specimens (Es) are calculated using Eq. (1):

$$\frac{1}{{E}_{r}} = \frac{1 - {v}_{i}^{2}}{{E}_{i}} + \frac{1 - {v}_{s}^{2}}{{E}_{s}} \qquad ( 1 )$$

where the reduced modulus (Eᵣ) is measured by nanoindentation, using an indenter of known modulus (Eᵢ=1140 GPa) and Poisson's ratio (υᵢ=0.07). The Poisson's ratio for both ZrO₂ and HfO₂ based TBC specimens (υₛ) is taken to be 0.3.

The measurements on AN2 are taken only on the composite YSZ/Gd₂O₃ layer, and not on the thin Gd₂O₃ top layer. The elastic modulus values measured for AN2 (149 GPa) are consistent with industry standards for plasma sprayed 8YSZ. The wide spread of values is expected due to the wide range of microstructural features (e.g., splat interfaces, voids, fully/partially molten splats) in plasma sprayed coatings. The small scale of the nanoindents makes it likely that a given indentation would be on a single Gd₂O₃ or YSZ splat, but indentations at interfaces, splat boundaries, and other defects are possible. The addition of 30 wt % Gd₂O₃ is expected to lower the mean composite coating elastic modulus as compared to 7YSZ, due to the lower modulus of fully dense Gd₂O₃ (148 GPa), as compared to fully dense 7YSZ (˜220 GPa). Interestingly, the nanohardness values calculated (14.8 GPa) are between the industry standards (e.g., between 11 GPa and 20 GPa).

Microstructural Evolution Post-Engine Test

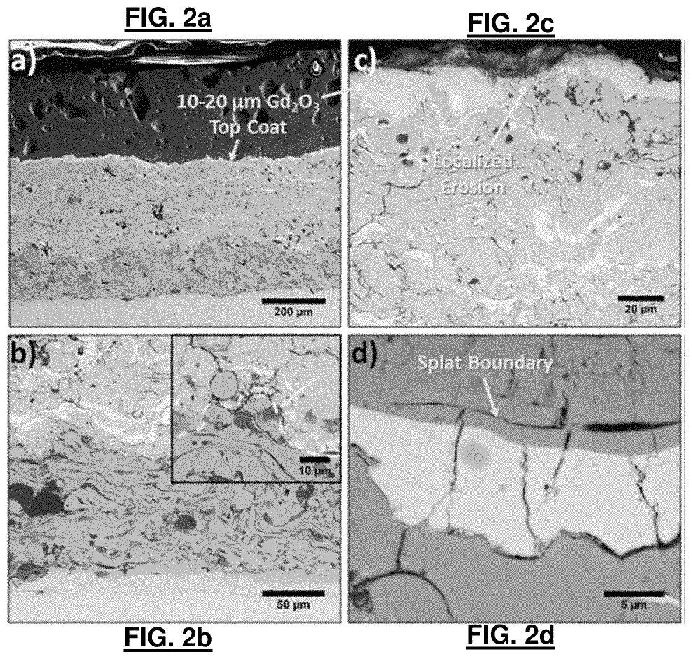

The microstructure of the AN2 composite and layered coating post engine test is provided in FIGS. 2a through 2d. FIG. 2a indicates that overall the coating has survived with only minimal signs of damage, and exhibits retention of structural integrity. However, signs of damage onset are evident in all layers of the coating, starting with the bond coat. FIG. 2b shows that significant oxide growth has occurred on the bond coat, and many of these oxides are situated at the interface with the composite TBC layer. The formation of these oxides builds up stress at the interface and microcracks can be seen to emanate from the interface and into the composite layer, as shown in the inset of FIG. 2b. Excessive cracking at the bond coat/TBC interface could lead to coating spallation. Another layer showing signs of damage is the thin Gd₂O₃ top coat, where signs of localized erosion can be seen in FIG. 2c). The as-deposited Gd₂O₃ top coat is ˜5 μm at the thinnest sections. However, in the post-engine tested coating there are localized regions with only 1-2 μm of the top coating remaining. Previous studies have observed Gd₂O₃ and Gd₂Zr₂O₇ to have lower erosion resistance than YSZ due to their lower fracture toughness. Further erosion of the Gd₂O₃ coating can lead to degradation of the CMAS resistance of this coating. Signs of damage are observed on the composite YSZ/Gd₂O₃ layer, in the form of microcracking within Gd₂O₃ splats, as shown in FIG. 2d. Crack initiation is expected to occur in the Gd₂O₃ phase due to its low toughness, however, it can be seen that microcracking appears to be largely contained to just the Gd₂O₃ phase. Cracks within Gd₂O₃ splats can be seen to be arrested at splat boundaries, and most cracks do not further propagate into the tougher YSZ phase.

Mechanical Property Evolution Post-Engine Test

The elastic modulus and nanohardness of the engine tested AN2 TBC are presented in Table 1. The evolution of mechanical properties can be understood based on the observed microstructural evolution. The elastic modulus and hardness of the composite layer in the AN2 coating decreased after service during the engine test. This can be attributed to the formation of cracks in the Gd₂O₃ layers. This coating is relatively dense in the as-deposited state and no signs of sintering or coarsening are observed post-engine test. A decrease in elastic modulus was observed in the plasma sprayed YSZ during high temperature (1121° C.) thermal cycling tests, due to cracking.

It should be mentioned that the residual stress state during and post engine test are likely different from that in the as-deposited coatings. The presence and evolution of residual stresses likely impact the mechanical behavior; e.g., cracking within layers and at interfaces likely has contributions from residual stresses and CTE mismatch stresses. The resulting microstructural changes due to the exposure to the engine environment are likely what dominate the corresponding changes in mechanical properties that are measured.

CMAS Adhesion and CMAS/TBC Interface

All of the coatings tested have some degree of CMAS accumulation present as seen in FIGS. 2a through 2d. The extent of CMAS deposition is quantified by measuring the maximum thickness of the CMAS deposits at various locations along the airfoil geometry: the leading edge (LE), the airfoil pressure side (PS) near the LE, on the PS near the first internal wall or cell, the PS near the trailing edge (TE), and the TE itself. The maximum thickness is of importance as this metric would be most indicative of potential airflow blockage. Accumulation of CMAS deposits is typically greatest at the leading edge, likely due to the stagnation point at the leading edge of the airfoil.

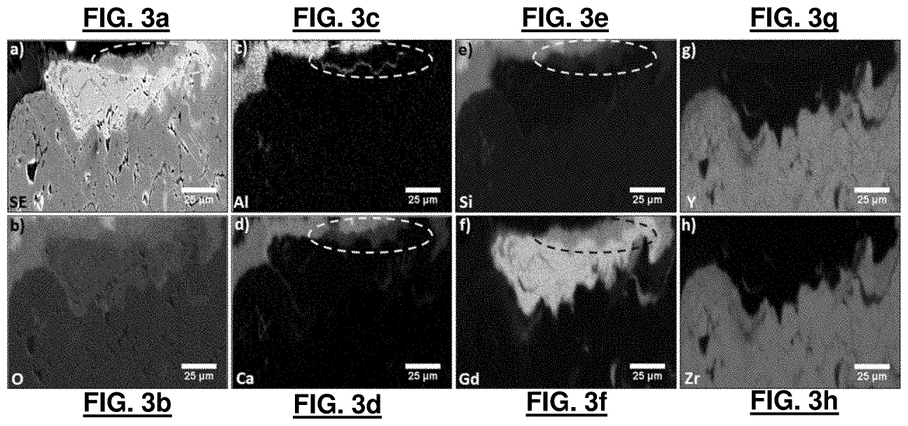

The interface of the AN2 TBC with the CMAS deposits is characterized in order to understand the degree of CMAS attack. The size of CMAS deposits is influenced by the initial adhesion of the CMAS deposits onto the TBC. Greater adhesion will enable further accumulation of CMAS to build up. The degree of adhesion will be directly influenced by the nature of the interface and whether any reactions took place. FIGS. 3a through 3h provide EDS maps of the most common CMAS constituent elements as well as of the AN2 TBC elements. The maps provide evidence that the Gd₂O₃ top coat forms a reaction product with the CMAS. Circled regions on the maps denote the reaction products, which primarily comprises of O, Ca, Si, and Gd. The presence of Gd with the molten CMAS suggests the formation of a Gd₈Ca₂(SiO₄)O₂ apatite phase. Another smaller and segregated phase in the reaction layer contains O, Al, and Gd, indicating a possible gadolinium aluminate phase. These reactions inhibit the CMAS from penetrating through the TBC. Inhibiting penetration provides less of an ‘anchor’ onto the TBC that would be expected to reduce adherence onto the TBC as mechanical interlocking between TBC and CMAS phases would be absent, analogous to how a coating has lower adhesion to the substrate when mechanical interlocking is absent. It is observed that some areas of the AN2 coating no longer has the Gd₂O₃ coating, and these areas has some minor infiltration of Ca and Si rich CMAS. A thicker and more erosion resistant Gd2O3 layer is likely needed in conditions with more prolonged CMAS exposure.

CMAS Microstructure

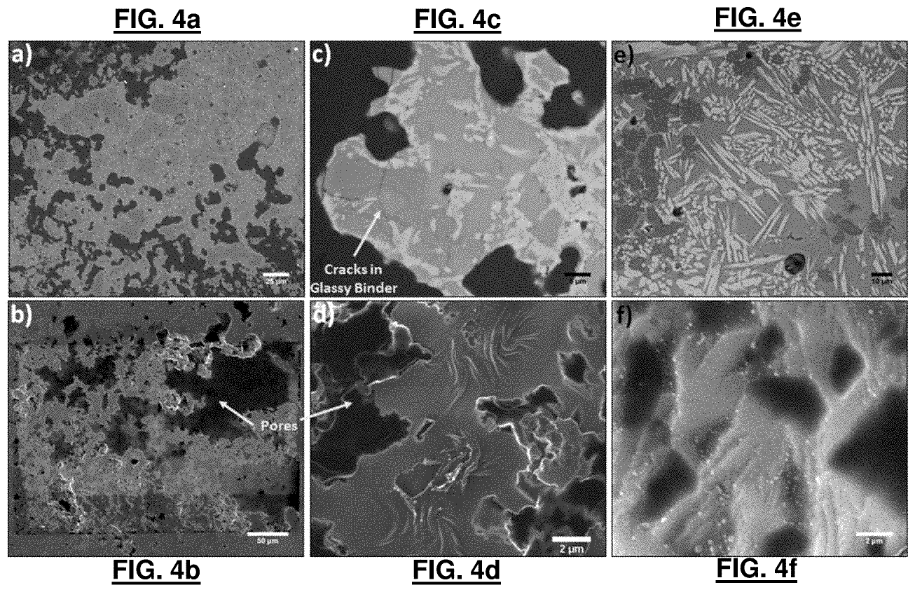

CMAS deposits on engine tested TBCs comprises of several phases and have multi-length-scale porosity. FIG. 4a shows pore sizes range from a few microns to 20-30 μm pores. The FIB polished CMAS deposit in FIG. 4b shows pores nearly 100 μm wide. The CMAS itself comprises of several crystalline phases embedded within a glassy binder. FIG. 4c shows that the binder lacks any discernible grain growth and contains several cracks that indicate it is relatively brittle. FIG. 4d shows several ‘swirl’ features within the glassy phase. These swirls are thought to form due to the rapid solidification of the viscous molten CMAS. The molten CMAS is likely to flow until it is solidified due to the high-pressure field from the flow within the gas turbine engine. FIG. 4e shows the various morphologies of the crystalline phases in the binder, with most appearing to have a needle-like structure. A lower contrast phase with an equiaxed morphology is present to a lesser degree. An ion-induced secondary electron image of a FIB polished CMAS deposit reveals that 100-200 nm particles are present throughout the binder as well as provided in FIG. 4f.

As described above, several approaches for damage tolerant and CMAS-resistant thermal barrier coatings are experimentally evaluated under sand laden combustion flows within a full-scale engine test. The approaches include an air plasma sprayed composite and layered coating (AN2), which demonstrates promising results in terms of retaining structural and microstructural integrity, with minimal CMAS accumulation. Mechanical properties in this coating undergo only minimal changes after exposure to the engine test, and only a slight decrease in modulus and hardness are observed due to cracking within the Gd₂O₃ splats within the YSZ/Gd₂O₃ layer. The ˜10 μm Gd₂O₃ top coat appears to react with CMAS deposits, thereby preventing infiltration. However, improved erosion resistance is needed, as many segments of the engine tested AN2 coating no longer has the thin Gd₂O₃ layer.

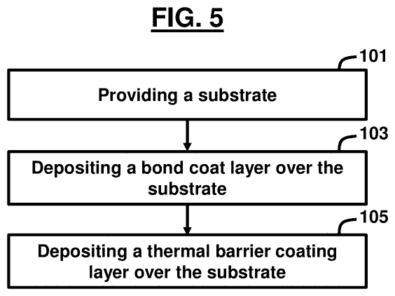

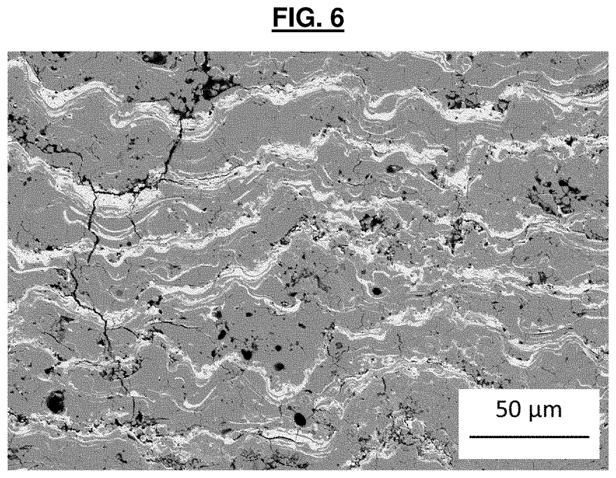

FIG. 5 is a flowchart illustrating a method of forming a layered or gradient composite structure according to an embodiment herein. The method comprises providing (101) a substrate; depositing (103) a bond coat layer over the substrate; and depositing (105) a TBC layer over the substrate. The TBC layer comprises CMAS-resistant RE oxide powder blended with YSZ. The TBC layer may be deposited using an air plasma spray. The TBC layer may be deposited using a solution precursor plasma spray. The TBC layer may be deposited using a suspension plasma spray. The TBC layer may be deposited using electron beam-physical vapor deposition. The TBC layer may be deposited using sol-gel deposition. The TBC layer may be deposited using aerosol deposition. The TBC layer may be deposited using chemical vapor deposition. The method may further comprise depositing the bond coat layer on the substrate prior to depositing the TBC layer. The TBC layer may be deposited at a thickness of approximately 100 to 1000 μm. FIG. 6 illustrates an example YSZ-RE oxide blend composite microstructure according to an embodiment herein.

The embodiments herein provide a blended composite coating with enhanced CMAS resistance. The composite approach utilizes advantageous properties of YSZ with that of RE oxides. Enhanced CMAS-phobicity is observed relative to conventional coatings in a full-scale gas turbine engine evaluation with sand ingestion conditions. The composite approach combines the properties of two types of oxides and varies the mixing concentration to achieve the desired functionalities of CMAS-phobicity, low thermal conductivity, high strain tolerance and creep resistance. The coating utilizes a composite approach within the primary layer in the coating, instead of utilizing distinct layers throughout the entire coating. The composite approach enables properties of each oxide material to be realized at a smaller micro scale (i.e., mixing at the splat level), thereby providing improved and more homogenous properties.

The embodiments herein may be used in rotorcraft, aircraft, and turbine-powered ground vehicles in order to protect critical engine components from damage caused by environmental particulates. Moreover, the embodiments herein may drastically increase life and maintenance period intervals (thereby reducing the maintenance and replacement cost significantly) by limiting the accumulation of environmental particulates and the subsequent reactions that take place. Furthermore, the embodiments herein may be used in aviation engines to increase their capability to perform in particulate laden environments such as volcanic ash plumes in the Pacific Ocean, sandy environments in southwest Asia and Africa, as well as heavily polluted air in large metropolitan cities. Additionally, the embodiments herein could be used in land-based gas turbine power-plants that generate energy, to prevent accumulation of fly ash and related chemical degradation. This can increase gas turbine efficiency and increase maintenance intervals.

Other uses for the embodiments herein are for turbine-powered land vehicles operating in austere environments, as well as for land-based gas turbine engines that generate energy, especially in systems designed for non-traditional, “dirty” fuels such as syngas where the presence of particulates in the fuel is possible. The coatings may have suitability for furnace applications to protect temperature sensitive components from thermal degradation while providing a non-reactive protective layer to reduce adhesion of foreign chemistries or compounds released during heat treatment of parts in the furnace.

The foregoing description of the specific embodiments will so fully reveal the general nature of the embodiments herein that others may, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein may be practiced with modification within the spirit and scope of the appended claims.

What is claimed is:

1. A thermal barrier coating (TBC) material comprising calcia-magnesia-alumino-silicate (CMAS)-resistant rare-earth (RE) oxide powder blended with yttria-stabilized zirconia (YSZ).

2. The material of claim 1, wherein the RE oxide powder comprises any of gadolinium oxide, samarium oxide, ytterbium oxide, cerium oxide, or a combination thereof.

3. The material of claim 1, wherein the RE oxide powder comprises gadolinium zirconate (GZO).

4. A composite structure comprising:
a substrate;
a bond coat; and
a thermal barrier coating (TBC) over the bond coat, wherein the TBC comprises calcia-magnesia-alumino-silicate (CMAS)-resistant rare-earth (RE) oxide powder blended with yttria-stabilized zirconia (YSZ).

5. The composite structure of claim 4, wherein the substrate comprises a metallic substrate.

6. The composite structure of claim 4, wherein the substrate comprises a ceramic substrate.

7. The composite structure of claim 4, wherein the RE oxide powder is approximately 10 to 90 weight % of the thermal barrier coating.

8. The composite structure of claim 4, wherein the TBC is approximately 100 to 1000 μm in thickness.

9. The composite structure of claim 4, wherein the RE oxide powder comprises any of gadolinium oxide, samarium oxide, ytterbium oxide, cerium oxide, or a combination thereof.

10. The composite structure of claim 4, wherein the RE oxide powder comprises gadolinium zirconate (GZO).

11. A method of forming a layered or gradient composite structure, the method comprising:
providing a substrate;
depositing a bond coat layer over the substrate; and
depositing a thermal barrier coating (TBC) layer over the substrate, wherein the TBC layer comprises calcia-magnesia-alumino-silicate (CMAS)-resistant rare-earth (RE) oxide powder blended with yttria-stabilized zirconia (YSZ).

12. The method of claim 11, wherein the TBC layer is deposited using an air plasma spray.

13. The method of claim 11, wherein the TBC layer is deposited using a solution precursor plasma spray.

14. The method of claim 11, wherein the TBC layer is deposited using a suspension plasma spray.

15. The method of claim 11, wherein the TBC layer is deposited using electron beam-physical vapor deposition.

16. The method of claim 11, wherein the TBC layer is deposited using sol-gel deposition.

17. The method of claim 11, wherein the TBC layer is deposited using aerosol deposition.

18. The method of claim 11, wherein the TBC layer is deposited using chemical vapor deposition.

19. The method of claim 11, further comprising depositing the bond coat layer on the substrate prior to depositing the TBC layer.

20. The method of claim 11, wherein the TBC layer is deposited at a thickness of approximately 100 to 1000 μm.
